(19) United States
(12) Patent Application Publication
(10) Pub. No.: US 2026/0082645 A1
(43) Pub. Date: Mar. 19, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kentaro ICHINOSEKI, Higashimurayama Tokyo (JP)

(21) Appl. No.: 19/039,253

(22) Filed: Jan. 28, 2025

(30) Foreign Application Priority Data
Sep. 18, 2024 (JP) 2024-161254

(51) Int. Cl. H10D 62/10; H10D 30/66; H10D 64/00; H10D 64/27; H10D 64/66; H10D 84/83

(52) U.S. Cl. CPC H10D 62/127; H10D 30/668; H10D 64/117; H10D 64/519; H10D 84/839; H10D 64/665

(57) ABSTRACT

A semiconductor device in an embodiment includes a plurality of first trenches which are recessed on one side in a thickness direction of a semiconductor substrate and have a first electrode accommodated therein. The semiconductor device includes a second trench which is recessed on the one side in the thickness direction and has a second electrode accommodated therein. When viewed from the thickness direction, the second trench surrounds each of the plurality of first trenches. The second trench includes a plurality of first extension portions which extend in a first direction which is orthogonal to the thickness direction and a plurality of second extension portions which extend in a second direction which is orthogonal to the thickness direction and intersects the first direction. A width of each of the plurality of second extension portions is narrower than a width of each of the plurality of first extension portions.

### CROSS-REFERENCE TO RELATED APPLICATION

This application is based upon and claims the benefit of priority from Japanese Patent Application No. 2024-161254, filed on Sep. 18, 2024, the entire contents of which are incorporated herein by reference.

### FIELD

Embodiments described herein relate generally to a semiconductor device.

### BACKGROUND

As a constitution for increasing the cell breakdown voltage of a semiconductor device having a trench-type field plate electrode structure, a semiconductor device having a constitution in which a field plate electrode is embedded in each trench disposed in a dot pattern is known. In such a semiconductor device, in order to reduce an on-resistance, reducing a gap between the field plate electrodes is required. Here, if the gap between the field plate electrodes is reduced by shortening a distance between a carrier extraction layer and an insulating film which insulates a gate electrode, there is a concern concerning that a threshold voltage of the semiconductor device will increase.

### BRIEF DESCRIPTION OF THE DRAWINGS

FIG. 1 is a plan view showing a semiconductor device in a first embodiment.

FIG. 2 is a cross-sectional view showing the semiconductor device in the first embodiment and taken along line II-II in FIG. 1.

FIG. 3 is a cross-sectional view showing the semiconductor device in the first embodiment and taken along line III-III in FIG. 1.

FIG. 4 is a first cross-sectional view showing a process of producing a semiconductor device in an embodiment.

FIG. 5 is a second cross-sectional view showing a process of producing a semiconductor device in an embodiment.

FIG. 6 is a third cross-sectional view showing a process of producing a semiconductor device in an embodiment.

FIG. 7 is a fourth cross-sectional view showing a process of producing a semiconductor device in an embodiment.

FIG. 8 is a fifth cross-sectional view showing a process of producing a semiconductor device in an embodiment.

FIG. 9 is a plan view showing a semiconductor device in a second embodiment.

FIG. 10 is a plan view showing a semiconductor device in a third embodiment.

FIG. 11 is a plan view showing a semiconductor device in a fourth embodiment.

### DETAILED DESCRIPTION

A semiconductor device in an embodiment includes a plurality of first trenches which are recessed on one side in a thickness direction of a semiconductor substrate and have a first electrode accommodated therein. The semiconductor device includes a second trench which is recessed from a surface to the one side in a thickness direction and a second electrode accommodated therein. The semiconductor device includes a first conductivity type base layer which is disposed between the first trench and the second trench and surrounds the first electrode. The semiconductor device includes a second conductivity type source layer which is disposed on the other side of the base layer in the thickness direction, in contact with the base layer, and surrounds the first electrode. The semiconductor device includes a second conductivity type drift layer which is disposed on the one side of the base layer in the thickness direction and in contact with the base layer. The semiconductor device includes a source electrode which is disposed on the other side of the semiconductor substrate in the thickness direction and electrically connected to the plurality of first electrodes and the source layer. When viewed in the thickness direction, the second trench surrounds each of the plurality of first trenches.

The second trench includes a plurality of first extension portions which extend in a first direction which is orthogonal to the thickness direction and a plurality of second extension portions which extend in a second direction which is orthogonal to the thickness direction and intersects the first direction. A width of each of the plurality of second extension portions is narrower than a width of each of the plurality of first extension portions.

A semiconductor device according to embodiments will be described below with reference to the drawings.

A direction in which a Z axis shown in each of the drawings extends corresponds to a thickness direction of the semiconductor device. A side (+Z side) to which an arrow in a Z-axis direction is directed corresponds to a lower side of the semiconductor device. A side (-Z side) opposite to the side to which the arrow in the Z-axis direction is directed corresponds to an upper side of the semiconductor device. In the following description, the lower side of the semiconductor device will be referred to as a “lower side” or “one side in a thickness direction,” the upper side of the semiconductor device will be referred to as an “upper side” or “the other side in the thickness direction,” and the thickness direction of the semiconductor device will be simply referred to as a “thickness direction. ” Each of the terms “upper side” and “lower side”does not indicate a relationship with the direction of gravity.

A first direction D1 shown in each of the drawing corresponds to a direction which is orthogonal to the thickness direction.

A second direction D2 shown in each of the drawing corresponds to a direction which is orthogonal to the thickness direction and intersects with the first direction D1.

In this specification, expressions such as “orthogonal,” “the same,” and “similar,” as well as values of length and angle used for specifying the shape of each part constituting the semiconductor device and the degree of the relative positional relationship between each of the parts are to be interpreted not as being bound by strict meanings but as including the range in which similar functions can be expected and the range of design tolerances.

In this specification, notations such as N⁺, N⁻, P⁺, and P⁻ represent a relative magnitude relationship of carrier concentration in each conductivity type. N⁺ indicates that a concentration of N-type carriers thereof is relatively higher than that of N⁻. P⁺ indicates that a concentration of P-type carriers thereof is relatively higher than that of P⁻. Furthermore, in this specification, a P-type is a first conductivity type and an N-type is a second conductivity type.

### First Embodiment

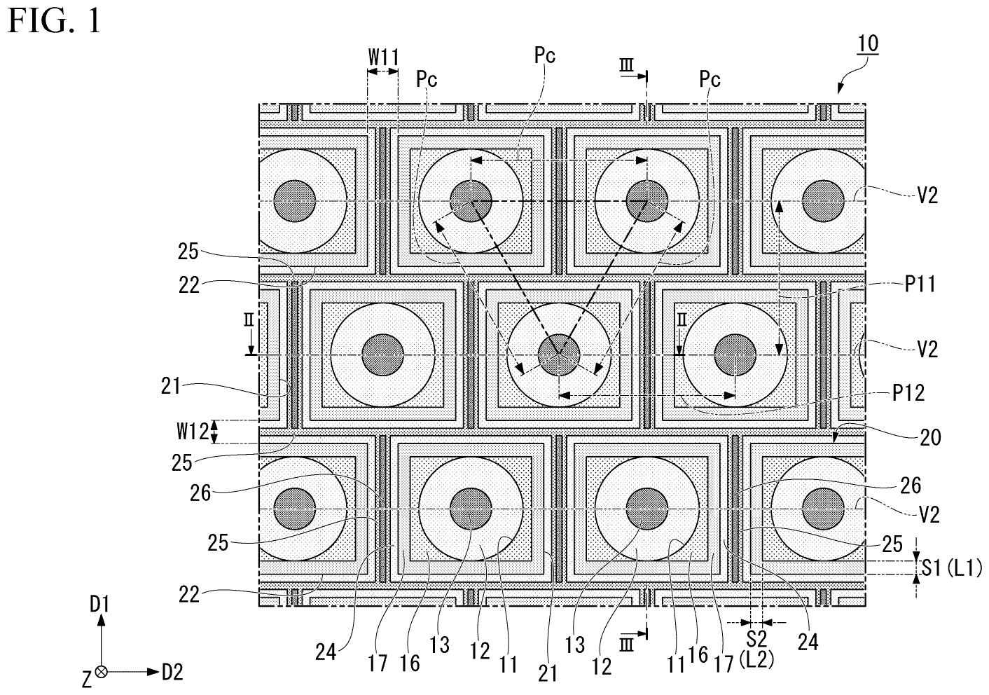

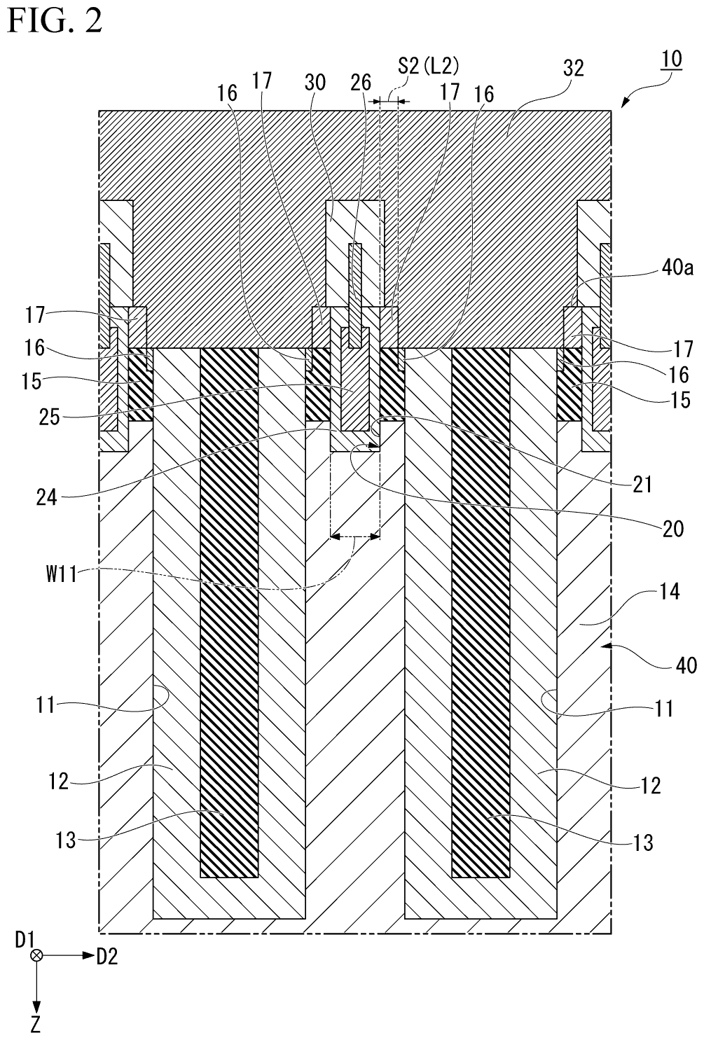

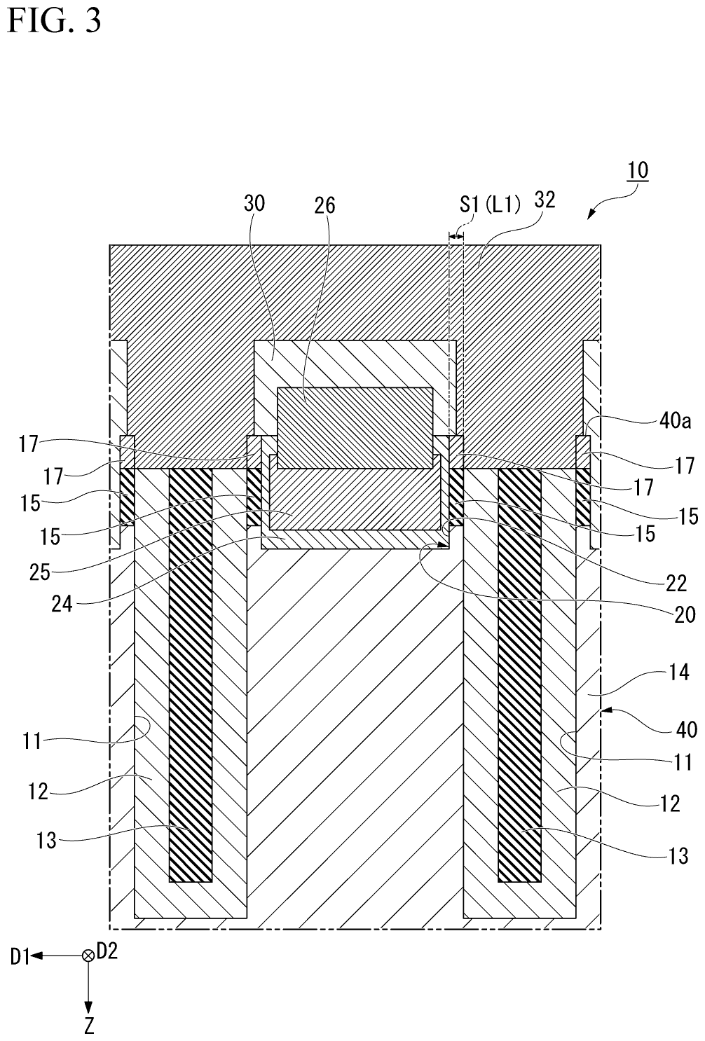

FIG. 1 is a plan view showing a semiconductor device 10 in the embodiment. In FIG. 1, the description of an insulation layer 30 and a source electrode 32 which will be described later are omitted. FIG. 2 is a cross-sectional view showing the semiconductor device 10 in the embodiment and taken along line II-II in FIG. 1. FIG. 3 is a cross-sectional view showing the semiconductor device 10 in the embodiment and taken along line III-III in FIG. 1. The semiconductor device 10 in the embodiment is a semiconductor device such as a metal-oxide-semiconductor field-effect transistor (MOSFET) or an insulated gate bipolar transistor (IGBT). As shown in FIG. 1, the semiconductor device 10 includes a plurality of first trenches 11 and a second trench 20. As shown in FIG. 2, the semiconductor device 10 includes a semiconductor substrate 40, the insulation layer 30, and the source electrode 32.

Each of the plurality of first trenches 11 is a recess recessed from a surface 40a of the semiconductor substrate 40 toward the lower side, that is, toward one side (+Z side) in the thickness direction. As shown in FIG. 1, when viewed in the thickness direction, each of the first trenches 11 has a substantially circular shape. When viewed in the thickness direction, a shape of each of the first trenches 11 may be a rectangular shape or another shape such as a hexagonal shape. The first trenches 11 are disposed in a staggered manner in a direction which is orthogonal to the thickness direction. More specifically, a plurality of first trench rows each composed of the plurality of first trenches 11 disposed side by side at intervals in the second direction D2 are disposed at intervals from each other in the first direction D1. In the embodiment, when viewed from the first direction D1, the first trenches 11 included in the two first trench rows disposed adjacent to each other in the first direction D1 are disposed at positions in which they are shifted in the second direction D2. In the embodiment, the second direction D2 is orthogonal to the first direction D1. The plurality of first trenches 11 constituting a first trench row may be disposed side by side at intervals in a direction which is different from the second direction D2.

Imaginary lines V2 shown in FIG. 1 are imaginary lines which extend in the second direction D2 and pass through centers of the plurality of first trenches 11. In the embodiment, a gap in the first direction D1 between imaginary lines V2 adjacent to each other in the first direction D1 among the plurality of imaginary lines V2, that is, a gap P11 between the first trenches 11 in the first direction D1, is smaller than a gap P12 between the first trenches 11 in the second direction D2. Furthermore, in the embodiment, when viewed from the thickness direction, lengths Pc of three sides of a triangle, having centers of the three first trenches 11 disposed adjacent to each other as vertexes, are the same. For this reason, the gaps Pc between the first trenches 11 all have the same length.

As shown in FIGS. 2 and 3, each of the first trenches 11 has a first insulating film 12 and a first electrode 13 accommodated therein. The first insulating film 12 is formed on an inner surface of the first trench 11. The first insulating film 12 insulates the first electrode 13 from each of a drift layer 14, a base layer 15, and a carrier extraction layer 16. As materials which constitute the first insulating film 12, for example, silicon oxide, silicon nitride, and the like can be used. As shown in FIG. 1, when viewed in the thickness direction, the first insulating film 12 has a substantially annular shape in which it surrounds the first electrode 13.

As shown in FIG. 2, the first electrode 13 has a substantially cylindrical shape in which it extends in the thickness direction inside the first trench 11. As shown in FIG. 1, when viewed in the thickness direction, the first insulating film 12 is a substantially circular shape. When viewed in the thickness direction, a shape of the first electrode 13 may be a rectangular shape or another shape such as a hexagonal shape. As shown in FIG. 2, the first electrode 13 is insulated from each of the drift layer 14, the base layer 15, and the carrier extraction layer 16 using the first insulating film 12. In the embodiment, the first electrode 13 is a field plate electrode. In the embodiment, the first electrode 13 is made of, for example, polysilicon. The first electrode 13 has conductivity. An upper end of the first electrode 13 is connected to the source electrode 32.

As shown in FIGS. 2 and 3, the base layer 15 is disposed between the first trench 11 and the second trench 20. The base layer 15 surrounds the first electrode 13. Although not shown in the drawings, the base layer 15 has a tubular shape in which it extends in the thickness direction. The base layer 15 is in contact with the first insulating film 12 and a second insulating film 24. In the embodiment, the base layer 15 is a first conductivity type, that is, a P⁻-type silicon layer, formed by implanting P-type impurity ions such as boron into a part of the drift layer 14 formed of an N-type silicon layer and subjecting it to thermal diffusion.

The carrier extraction layer 16 substantially surrounds a portion including an upper end of the first insulating film 12. The carrier extraction layer 16 is electrically connected to the base layer 15. The carrier extraction layer 16 is connected to the source electrode 32. The carrier extraction layer 16 has a substantially tubular shape in which it extends in the thickness direction. As shown in FIG. 1, when viewed in the thickness direction, the carrier extraction layer 16 substantially surrounds each of the first trenches 11. The dimension in the second direction D2 of the carrier extraction layer 16 is larger than the dimension in the second direction D2 of the first trench 11. The dimension in the first direction D1 of the carrier extraction layer 16 is substantially the same as the dimension in the first direction D1 of the first trench 11. The dimension in the first direction D1 of the carrier extraction layer 16 may be larger than the dimension in the first direction D1 of the first trench 11. In the embodiment, the carrier extraction layer 16 is a P⁺-type silicon layer formed by implanting P-type impurity ions such as boron into a part of each of the base layer 15 and a source layer 17 and subjecting it to thermal diffusion.

As shown in FIG. 2, the source layer 17 is disposed above the base layer 15.

The source layer 17 is in contact with the base layer 15. The source layer 17 is in contact with the source electrode 32. Thus, the source layer 17 is electrically connected to the source electrode 32. As shown in FIG. 1, when viewed in the thickness direction, the source layer 17 surrounds the first electrode 13. When viewed from the thickness direction, the source layer 17 surrounds the carrier extraction layer 16. In the embodiment, the source layer 17 is a second conductivity type, that is, an N⁺-type silicon layer, formed by implanting N-type impurity ions such as phosphorus and arsenic at a high concentration into a part of the base layer 15 and subjecting it to thermal diffusion. In the embodiment, a dimension S2 in the second direction D2 of the source layer 17 shown in FIG. 2 and a dimension S1 in the first direction D1 of the source layer 17 shown in FIG. 3 are the same dimension.

The drift layer 14 is disposed below the base layer 15. The drift layer 14 is in contact with the base layer 15. The drift layer 14 is in contact with each of the first insulating film 12 and the second insulating film 24. In the embodiment, the drift layer 14 is an N⁻-type silicon layer.

As shown in FIG. 2, the second trench 20 is a recess recessed from a surface 40a of the semiconductor substrate 40 toward the lower side, that is, toward the one side in the thickness direction (+Z side). The dimension in the thickness direction of the second trench 20 is smaller than the dimension in the thickness direction of each of the first trenches 11. As shown in FIG. 1, when viewed in the thickness direction, the second trench 20 surrounds each of the plurality of first trenches 11. More specifically, when viewed in the thickness direction, the second trench 20 surrounds the source layer 17 which surrounds each of the first electrodes 13. The second trench 20 has a plurality of first extension portions 21 and a plurality of second extension portions 22.

Each of the first extension portions 21 is a portion of the second trench 20 which extends in the first direction D1. In the embodiment, each of the first extension portions 21 extends linearly in the first direction D1. Each of the plurality of first extension portions 21 is disposed between the first trenches 11 disposed adjacent to each other in the second direction D2.

Each of the second extension portions 22 is a portion of the second trench 20 which extends in the second direction D2. In the embodiment, each of the second extension portions 22 extends linearly in the second direction D2. Each of the plurality of second extension portions 22 is disposed between the first trenches 11 disposed adjacent to each other in the first direction D1. Both ends in the first direction D1 of each of the first extension portions 21 are connected to the second extension portions 22 that are different from each other. Thus, each of the first extension portions 21 is connected to each other via each of the second extension portions 22. Furthermore, each of the second extension portions 22 is connected to each other via each of the first extension portions 21. A width W12 of each of the plurality of second extension portions 22 is narrower than a width W11 of each of the plurality of first extension portions 21. In other words, the width W11 of each of the plurality of first extension portions 21 is wider than the width W12 of each of the plurality of second extension portions 22.

As shown in FIGS. 2 and 3, the second trench 20 has the second insulating film 24 and a second electrode 25 accommodated therein. The second insulating film 24 is formed on an inner surface of the second trench 20. The second insulating film 24 insulates the second electrode 25 from each of the drift layer 14, the base layer 15, and the source layer 17. As materials which constitute the second insulating film 24, for example, silicon oxide, silicon nitride, or the like can be used. As shown in FIG. 1, when viewed in the thickness direction, the second insulating film 24 surrounds the source layer 17. When viewed from the thickness direction, the second insulating film 24 formed on an inner surface of the first extension portion 21 extends in the first direction D1 and the second insulating film 24 formed on an inner surface of the second extension portion 22 extends in the second direction D2.

As shown in FIG. 2, the second electrode 25 extends in the thickness direction in the second trench 20. The second electrode 25 is insulated from each of the drift layer 14, the base layer 15, and the source layer 17 using the second insulating film 24. In the embodiment, the second electrode 25 is a gate electrode. In the embodiment, the second electrode 25 is made of, for example, polysilicon. The second electrode 25 has conductivity.

As shown in FIG. 1, the second electrode 25 is provided inside the entire second trench 20. When viewed from the thickness direction, a portion of the second electrode 25 accommodated inside each of the first extension portions 21 extends in the first direction D1. When viewed from the thickness direction, a portion of the second electrode 25 accommodated inside each of the second extension portions 22 extends in the second direction D2.

As shown in FIG. 1, a conductive portion 26 is disposed in the second trench 20. More specifically, each of the plurality of first extension portions 21 has the conductive portion 26 disposed therein. In each of the plurality of second extension portions 22, the conductive portion 26 is not disposed. As shown in FIG. 2, the conductive portion 26 extends upward from an inside of the first extension portions 21. A portion on a lower side of the conductive portion 26 is located inside a portion of the second electrode 25 which is disposed in the first extension portions 21 and is connected to the second electrode 25. Thus, the conductive portion 26 is electrically connected to the second electrode 25. A portion on an upper side of the conductive portion 26 is located inside the insulation layer 30. Thus, the conductive portion 26 is insulated from the source electrode 32. Furthermore, the conductive portion 26 is insulated from each of the drift layer 14, the base layer 15, the source layer 17, and the source electrode 32 by the second insulating film 24.

In the embodiment, the conductive portion 26 is made of a metal. The conductive portion 26 is made of, for example, tungsten. The conductive portion 26 has conductivity. Therefore, a part of a gate current that is a current flowing through the second electrode 25 flows through the conductive portion 26. Thus, since a cross-sectional area through which the gate current flows can be increased as compared to the case in which the conductive portion 26 is not provided in each of the first extension portions 21, a gate resistance Rg that is an electrical resistance between one end of the second electrode 25 and the other end of the second electrode 25 can be reduced.

Also, in the embodiment, the resistivity of the conductive portion 26 is less than the resistivity of the second electrode 25. Thus, since it is easier to make the electrical resistance of the conductive portion 26 smaller than the electrical resistance of the second electrode 25, the gate resistance Rg can be more appropriately reduced.

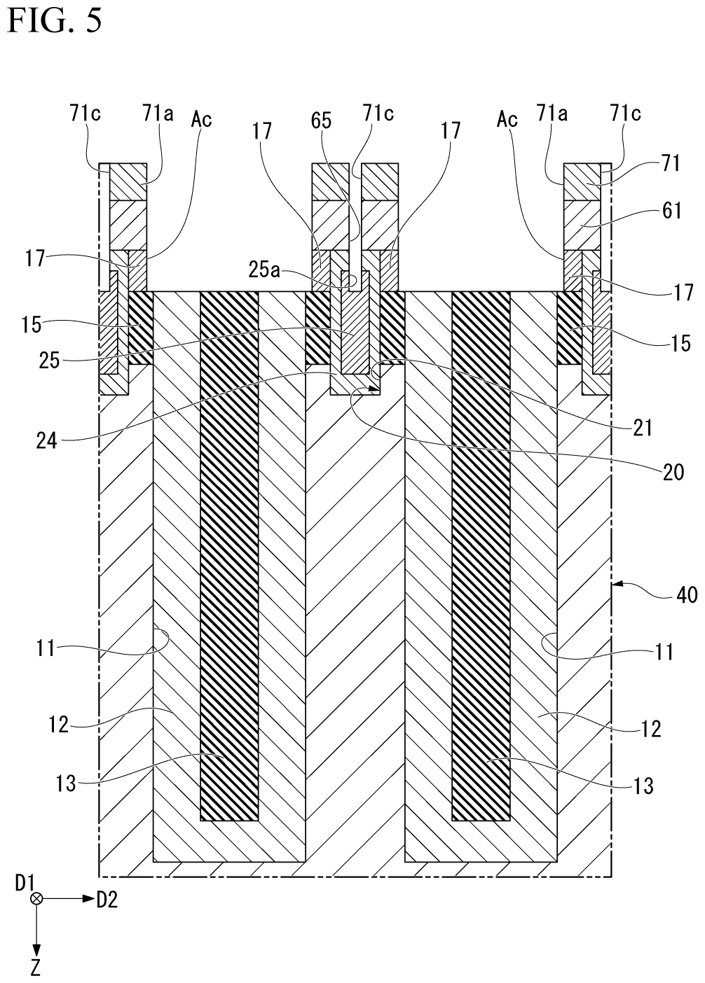

As will be described later, in the embodiment, the conductive portion 26 is formed by supplying tungsten, through a chemical vapor deposition method, into a concave portion 25a (refer to FIG. 5) and a third hole portion 65 (refer to FIG. 5) formed by etching each of the second insulating film 24 and the second electrode 25 using a resist 71 as a mask. For this reason, in order to reliably connect the second electrode 25 and the conductive portion 26, the width of the second electrode 25 needs to be made wider than a predetermined width. Therefore, it is difficult to narrow the width of the portion of the second trench 20 in which the conductive portion 26 is located.

On the other hand, in the embodiment, as described above, the conductive portion 26 is disposed in each of the first extension portions 21 and the conductive portion 26 is not disposed in each of the second extension portions 22. For this reason, in the embodiment, the width W12 of each of the second extension portions 22 can be narrower than the width W11 of each of the first extension portions 21. Thus, while keeping the dimension S2 in the second direction D2 of the source layer 17 and the dimension S1 in the first direction D1 of the source layer 17 the same dimension, the gap P11 between the first trenches 11 in the first direction D1 can be made smaller than the gap P12 between the first trenches 11 in the second direction D2. Therefore, a gap Pc between the first trenches 11 can be made smaller.

In the embodiment, the dimension S1 in the first direction D1 of the source layer 17 is the same dimension as a first distance L1 that is a distance between the carrier extraction layer 16 and the second insulating film 24 in the first direction D1. Furthermore, the dimension S2 in the second direction D2 of the source layer 17 is the same dimension as a second distance L2 that is a distance between the carrier extraction layer 16 and the second insulating film 24 in the second direction D2. As described above, in the embodiment, since the dimension S1 in the first direction D1 and the dimension S2 in the second direction D2 of the source layer 17 are the same dimension, the first distance L1 and the second distance L2 are the same dimension. Therefore, in the embodiment, by making the width W12 of each of the second extension portions 22 narrower than the width W11 of each of the first extension portions 21, the gap Pc between the first trenches 11 can be made small while keeping the first distance L1 and the second distance L2 the same dimension. Thus, since the first distance L1 can be prevented from becoming too short, a threshold voltage of the semiconductor device 10 can be prevented from increasing. Furthermore, since the gap Pc between the first trenches 11 can be made smaller, an on-resistance of the semiconductor device 10 can be reduced. That is to say, in the embodiment, since the width W12 of each of the second extension portions 22 is narrower than the width W11 of each of the first extension portions 21, the on-resistance can be reduced while suppressing an increase in the threshold voltage of the semiconductor device 10.

As shown in FIGS. 2 and 3, the insulation layer 30 covers a part of the source layer 17 and the conductive portion 26 from above. The insulation layer 30 insulates the conductive portion 26 from the source electrode 32. In the embodiment, the insulation layer 30 is a silicon oxide film.

The source electrode 32 is disposed above the semiconductor substrate 40. The source electrode 32 covers each of the first insulating films 12, each of the first electrodes 13, the insulation layer 30, and the like. The source electrode 32 is connected to each of the first electrode 13, the carrier extraction layer 16, and the source layer 17. Thus, each of the first electrode 13, the carrier extraction layer 16, and the source layer 17 is electrically connected to the source electrode 32. As described above, the carrier extraction layer 16 is electrically connected to the base layer 15. Thus, the source electrode 32 electrically connects each of the plurality of first electrodes 13 to the base layer 15. In the embodiment, the source electrode 32 is made of a metal material such as aluminum.

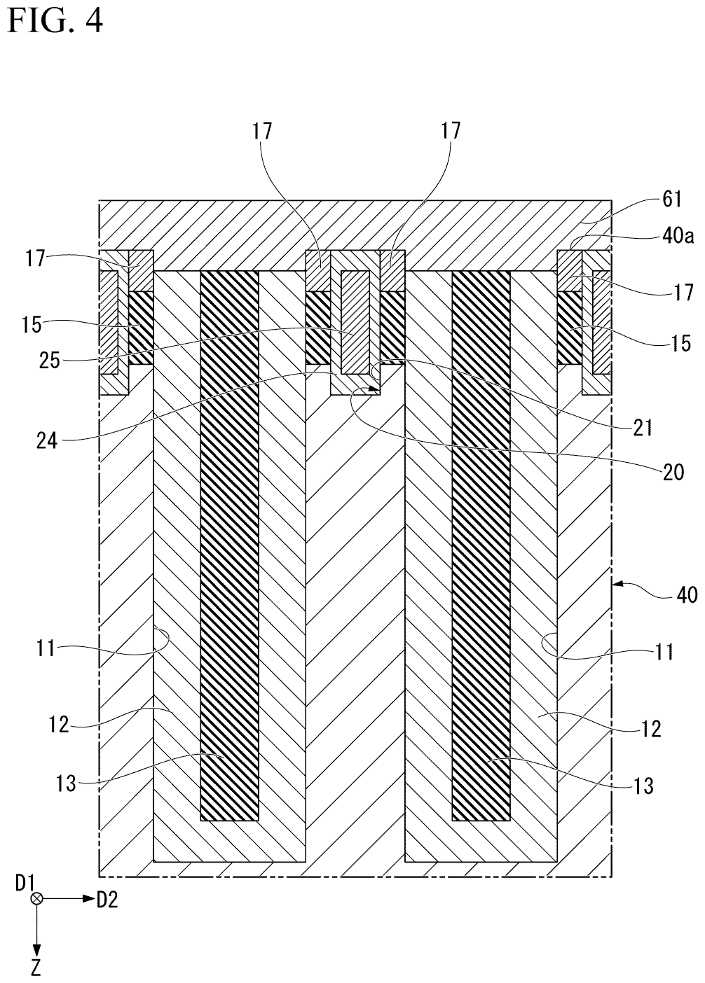

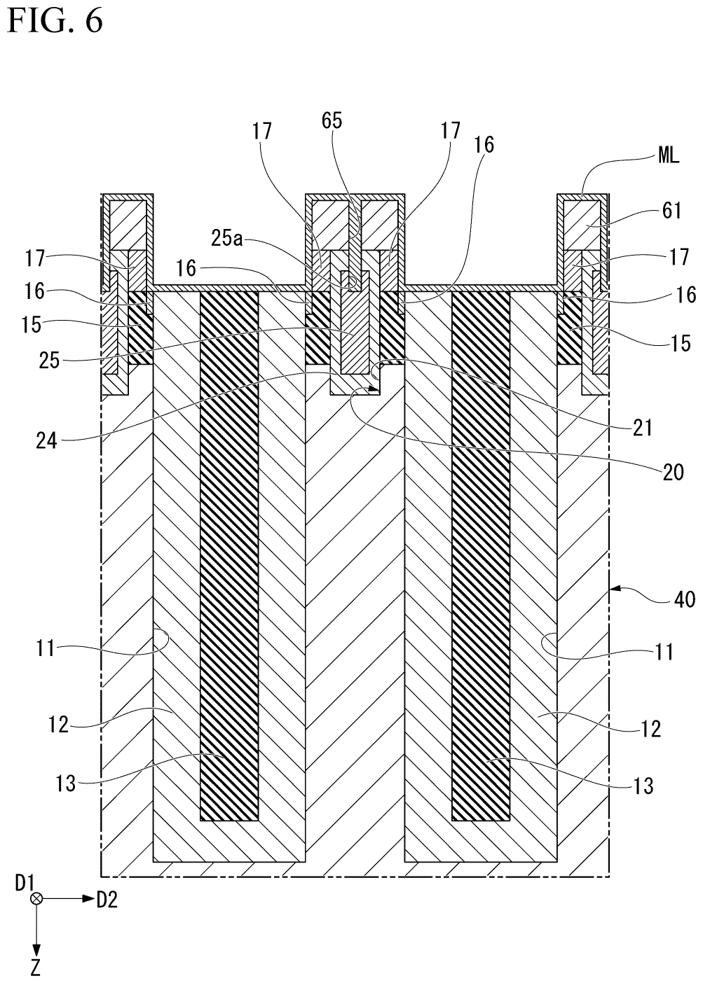

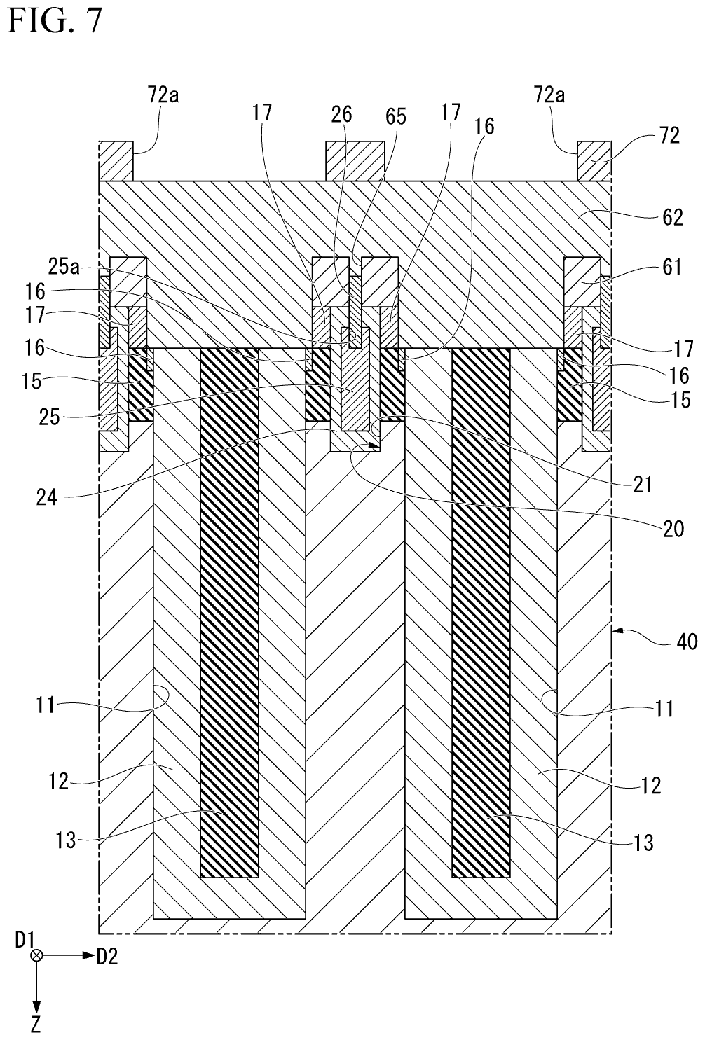

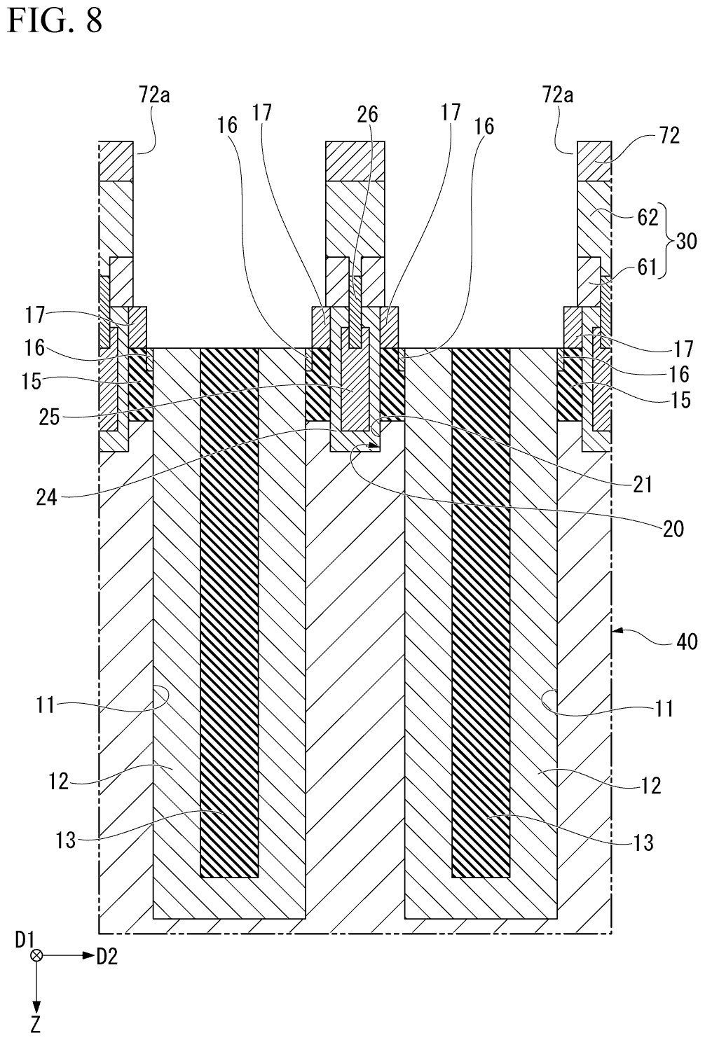

FIG. 4 is a first cross-sectional view showing a process of producing a semiconductor device 10 in an embodiment. FIG. 5 is a second cross-sectional view showing a process of producing a semiconductor device 10 of an embodiment. FIG. 6 is a third cross-sectional view showing a process of producing a semiconductor device 10 of an embodiment. FIG. 7 is a fourth cross-sectional view showing a process of producing a semiconductor device 10 of an embodiment. FIG. 8 is a fifth cross-sectional view showing a process of producing a semiconductor device 10 of an embodiment. A method of producing the semiconductor devices 10 in the embodiments will be described below. In the following description, the term “operator or the like” includes an operator who performs the tasks in each process, an assembly machine, and the like. The operation in each process may be performed by an operator alone, by an assembly machine alone, or by an operator and an assembly machine.

First, as shown in FIG. 4, the operator or the like forms a plurality of first trenches 11 in a semiconductor substrate 40. The operator or the like forms the plurality of first trenches 11 by forming an oxide film (not shown) on a surface 40a of the semiconductor substrate 40, and then etching the oxide film using a resist pattern through lithography as a mask and etching the semiconductor substrate 40 using the patterned oxide film as a mask. Subsequently, the operator or the like forms a first insulating film 12 which is made of silicon oxide, silicon nitride, or the like on an inner surface of each of the first trenches 11 through thermal oxidation or chemical vapor deposition (CVD). Subsequently, the operator or the like forms the first electrode 13 made of polysilicon inside each of the first trenches 11 through chemical vapor deposition. Subsequently, the operator or the like forms a silicon oxide film (not shown) on a surface of each of the first insulating films 12 and a surface of each of the first electrodes 13.

Subsequently, the operator or the like forms a second trench 20, a second insulating film 24, and a second electrode 25. The operator or the like forms the second trench 20 by forming an oxide film (not shown) on a surface 40a of the semiconductor substrate 40, and then etching the oxide film using a resist patterned through lithography as a mask and etching the semiconductor substrate 40 using the patterned oxide film as a mask. Subsequently, the operator or the like forms the second insulating film 24 which is made of silicon oxide, silicon nitride, or the like on an inner surface of the second trench 20 through thermal oxidation or chemical vapor deposition. Subsequently, the operator or the like forms a second electrode 25 made of polysilicon inside each second trench 20 through chemical vapor deposition. Subsequently, the operator or the like removes the silicon oxide film formed on the surface of the semiconductor substrate 40 through etching.

Subsequently, the operator or the like forms a base layer 15 and a source layer 17. The operator or the like forms the base layer 15 by implanting P-type impurity ions such as boron into a part of a surface of the drift layer 14 that is an N-type silicon layer, and subjecting it to thermal diffusion. Subsequently, the operator or the like forms the source layer 17 made of N+silicon by implanting N-type impurity ions such as phosphorus and arsenic at a high concentration into a surface of the base layer 15 and subjecting it to thermal diffusion.

Subsequently, as shown in FIG. 4, the operator or the like forms a first insulation layer 61 covering each of the first trench 11, the second trench 20, and the source layer 17. The operator or the like forms the first insulation layer 61 which is composed of a silicon oxide film through thermal oxidation or chemical vapor deposition.

Subsequently, as shown in FIG. 5, the operator or the like performs etching using a patterned resist 71 as a mask. In the embodiment, such etching is reactive ion etching (RIE). The resist 71 has a plurality of first hole portions 71a and a plurality of second hole portions 71c formed therein. When viewed in the thickness direction, an outer edge of each first hole portion 71a and the source layer 17 overlap. For this reason, a part of the first insulation layer 61 and a part of the source layer 17 are removed through etching. Thus, contact opening portions Ac are formed and the first insulating film 12 and the first electrode 13 are each exposed toward the upper side. Furthermore, through the above etching, a portion of the upper end side of each of the first electrodes 13 and a portion of the upper end side of each of the first insulating films 12 are also removed.

When viewed in the thickness direction, the second hole portions 71c and central portions of second electrodes 25 which are different from each other overlap. Portions of the second insulating film 24 and the first insulation layer 61 in which they and each of the second hole portions 71c overlap when viewed in the thickness direction are removed through etching and a third hole portion 65 which passes through the second insulating film 24 and the first insulation layer 61 in the thickness direction is formed. Furthermore, a portion of a portion on an upper side of the second electrode 25 in which it and each of the second hole portions 71c overlap when viewed in the thickness direction is removed through etching. Thus, the second electrode 25 has a concave portion 25a formed to be recessed downward.

Subsequently, as shown in FIG. 6, the operator or the like forms a carrier extraction layer 16. First, the operator or the like removes the resist 71 through etching. Subsequently, the operator or the like forms the carrier extraction layer 16 by implanting P-type impurity ions such as boron into a part of a base layer 15 via each of the contact opening portions Ac and subjecting it to thermal diffusion.

Subsequently, the operator or the like forms a conductive layer ML covering each of the first insulating films 12, each of the first electrodes 13, the first insulation layer 61, and the like. The operator or the like forms the conductive layer ML composed of tungsten through a chemical vapor deposition method. A part of the conductive layer ML extends into the concave portion 25a of the second electrode 25 through the third hole portion 65. A portion of the conductive layer ML which is formed inside the third hole portion 65 and inside the concave portion 25a forms a conductive portion 26.

Subsequently, the operator or the like removes a part of the conductive layer ML through etching. More specifically, the operator or the like removes, through etching, a portion of the conductive layer ML except for portions thereof located inside the third hole portion 65 and inside the concave portion 25a. As shown in FIG. 7, a portion on the upper side of the conductive layer ML formed inside the third hole portion 65 is removed through etching. Thus, the conductive portion 26 is formed.

Subsequently, the operator or the like forms a second insulation layer 62 covering each of the first insulating films 12, each of the first electrodes 13, and the first insulation layer 61, and the like. The operator or the like forms a second insulation layer 62 composed of a silicon oxide film through thermal oxidation or chemical vapor deposition.

Subsequently, the operator or the like performs etching using a patterned resist 72 as a mask. The resist 72 has a plurality of fourth hole portions 72a formed therein.

When viewed in the thickness direction, an outer edge of each of the fourth hole portions 72a and the source layer 17 overlap. For this reason, as shown in FIG. 8, a portion of the second insulation layer 62 in which the second insulation layer 62 and the fourth hole portions 72a overlap when viewed in the thickness direction is removed through etching. Thus, the upper end of each of the first insulating films 12 and the upper end of each of the first electrodes 13 are exposed upward. Furthermore, a part of the first insulation layer 61 is removed through etching. Thus, a part of the source layer 17 is exposed upward. The first insulation layer 61 and the second insulation layer 62 which are not removed through etching constitute the insulation layer 30. In the embodiment, such etching is reactive ion etching (RIE).

Subsequently, the operator or the like forms the source electrode 32 shown in FIG. 2 after removing the resist 72 by forming a film of a wiring layer (not shown) through a sputtering method or the like, and then etching the film using a resist patterned through lithography as a mask. In the embodiment, the source electrode 32 is made of a metal. In the embodiment, the source electrode 32 is made of a metal material such as aluminum. If the mask (not shown) is removed through etching, the semiconductor device 10 in the embodiment is completed and the process of producing the semiconductor device 10 is finished.

According to the embodiment, the semiconductor device 10 includes the plurality of first trenches 11 which are each recessed downward from the surface 40a of the semiconductor substrate 40, that is, recessed toward the one side (+Z side) in the thickness direction and have the first electrodes 13 accommodated therein, the second trench 20 which is recessed downward from the surface 40a and has the second electrode 25 accommodated therein, the first conductivity type, that is, P-type base layers 15 which are each disposed between the first trenches 11 and the second trench 20 and surround the first electrodes 13, the second conductivity type, that is, N-type source layers 17 which are disposed above the base layers 15, in contact with the base layers 15, and surround the first electrodes 13, the N-type drift layer 14 which is disposed below the base layers 15 and in contact with the base layers 15, and the source electrode 32 which are disposed above the semiconductor substrate 40 and electrically connected to the plurality of first electrodes 13 and the source layers 17. When viewed from the thickness direction, the second trench 20 surrounds each of the plurality of first trenches 11, the second trench 20 has the plurality of first extension portions 21 extending in the first direction D1 and the plurality of second extension portions 22 extending in the second direction D2, and the width W12 of each of the plurality of second extension portions 22 is narrower than the width W11 of each of the plurality of first extension portions 21. Thus, as described above, the gap (cell pitch) Pc between the first trenches 11 can be made smaller while keeping the first distance L1 that is the distance between the carrier extraction layer 16 and the second insulating film 24 in the first direction D1 and the second distance L2 that is the distance between the carrier extraction layer 16 and the second insulating film 24 in the second direction D2 the same dimension. Therefore, since the first distance L1 can be prevented from becoming too short, the threshold voltage of the semiconductor device 10 can be prevented from increasing. Furthermore, since it is easy to set the first distance L1 to an optimal length, the width of the base layer 15 can be prevented from becoming too wide. Thus, a decrease in the avalanche resistance of the semiconductor device 10 can be suppressed. In addition, as described above, since the gap Pc between the first trenches 11 can be made smaller, the on-resistance of the semiconductor device 10 can be reduced. Therefore, the on-resistance of the semiconductor device 10 can be reduced while suppressing an increase in the threshold voltage.

According to the embodiment, the conductive portion 26 which is connected to the second electrode 25 is disposed in each of the plurality of first extension portions 21. Thus, as described above, the width W12 of each of the plurality of second extension portions 22 can more easily be made narrower than the width W11 of each of the plurality of first extension portions 21. For this reason, as described above, the gap Pc between the first trenches 11 can be made smaller while keeping the first distance L1 and the second distance L2 the same dimension. Therefore, since the first distance L1 can be prevented from becoming too short, the threshold voltage of the semiconductor device 10 can be prevented from increasing. Furthermore, since the gap Pc between the first trenches 11 can be made smaller more easily, the on-resistance of the semiconductor device 10 can be reduced more suitably.

Also, in the embodiment, the conductive portion 26 which is connected to the second electrode 25 is disposed in each of the first extension portions 21. Thus, as described above, the gate resistance Rg can be reduced as compared to the case in which the conductive portion 26 is not provided in each of the first extension portions 21. Therefore, the potential of the entire second electrode 25 can be made uniform in an appropriate manner.

According to the embodiment, the resistivity of the conductive portion 26 is less than the resistivity of the second electrode 25. Thus, since the electrical resistance of the conductive portion 26 can be easily made smaller than the electrical resistance of the second electrode 25, the gate resistance Rg can be more suitably reduced. Therefore, the potential of the entire second electrode 25 can be more suitably made uniform.

According to the embodiment, the gap in the first direction D1 between the imaginary lines V2 adjacent to each other in the first direction D1 among the plurality of imaginary lines V2 extending in the second direction D2 and passing through the centers of the plurality of first trenches 11, that is, the gap P11 between the first trenches 11 in the first direction D1, is smaller than the gap P12 between the first trenches 11 in the second direction D2. Thus, in the first direction D1, the first trenches 11 can be disposed close to each other. Thus, the gap Pc between the first trenches 11 can be more suitably reduced. Therefore, the on-resistance of the semiconductor device 10 can be reduced more suitably.

According to the embodiment, when viewed from the thickness direction, the lengths of the three sides of a triangle, having centers of the three first trenches 11 disposed adjacent to each other as vertexes, are the same. Thus, the gaps between the first electrodes 13 can be made to be the same gap. Therefore, since the withstand voltage between the first electrodes 13 can be made uniform, the withstand voltage of the semiconductor device 10 can be increased.

According to the embodiment, each of the plurality of first extension portions 21 is disposed between the first trenches 11 adjacent to each other in the second direction D2 and each of the plurality of second extension portions 22 is disposed between the first trenches 11 disposed adjacent to each other in the first direction D1 and extends in a second direction D2 orthogonal to the first direction D1. For this reason, the gap between the second electrode 25 accommodated inside the second trench 20 and each of the first electrodes 13 accommodated inside each of the first trenches 11 can be prevented from becoming too large. Thus, since the concentration of the electric field on a portion of the second electrode 25 can be effectively prevented, the avalanche resistance of the semiconductor device 10 can be effectively increased.

### Second Embodiment

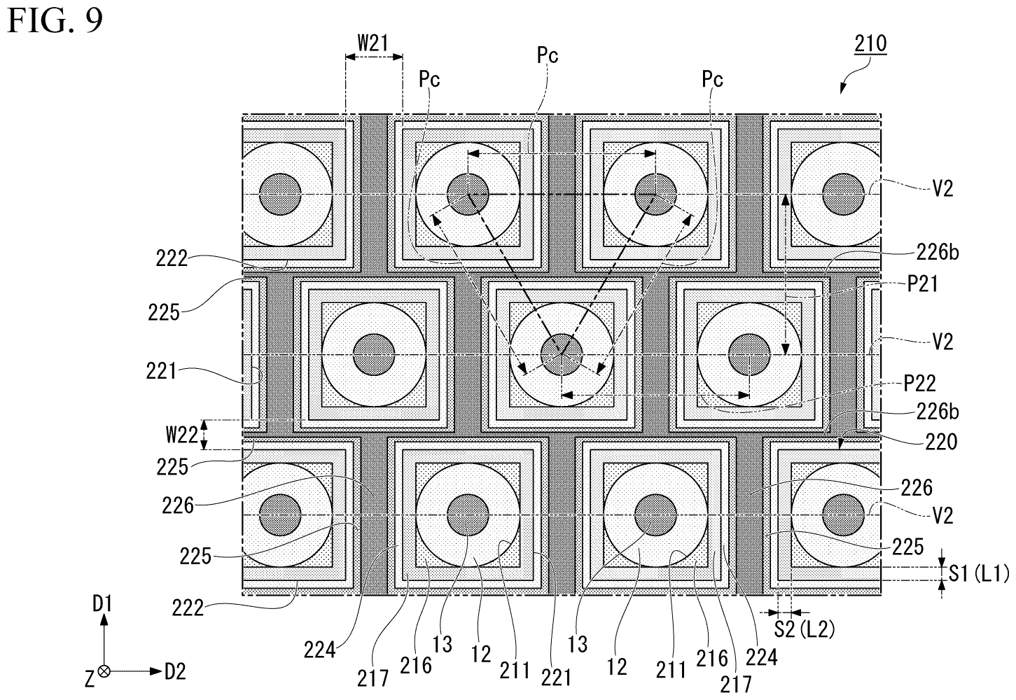

FIG. 9 is a plan view showing a semiconductor device 210 in the embodiment. A width W21 of first extension portions 221 in the embodiment is wider than the width W11 of the first extension portions 21 in the first embodiment described above and a width W22 of second extension portions 222 in the embodiment is greater than the width W12 of the second extension portions 22 in the first embodiment described above. In the following description, the same constituent elements as those in the above-described first embodiment are denoted by the same reference numerals and the description thereof will be omitted. A semiconductor device 210 in the embodiment includes a plurality of first trenches 211 and a second trench 220. The semiconductor device 210 includes the semiconductor substrate 40 (refer to FIG. 2), the insulation layer 30 (refer to FIG. 2), and the source electrode 32 (refer to FIG. 2).

As shown in FIG. 9, the first trenches 211 are disposed in a staggered manner in a direction which is orthogonal to the thickness direction. When viewed from the first direction D1, the first trenches 211 included in two first trench rows disposed adjacent to each other in the first direction D1 are disposed at positions in which they are shifted from each other in the second direction D2. In the embodiment, the second direction D2 is orthogonal to the first direction D1.

A gap in a first direction D1 between imaginary lines V2 disposed adjacent to each other in the first direction D1 among a plurality of imaginary lines V2 shown in FIG. 9, that is, a gap P21 between the first trenches 211 in the first direction D1, is smaller than a gap P22 between the first trenches 211 in a second direction D2. The gap P21 in the embodiment is larger than the gap P11 of the first embodiment described above and the gap P22 in the embodiment is larger than the gap P12 of the first embodiment described above. In the embodiment, when viewed from the thickness direction, lengths Pc of three sides of a triangle, having centers of three first trenches 211 disposed adjacent to each other as vertexes, are the same. For this reason, the gaps Pc between the first trenches 211 all have the same length. The first insulating film 12 and the first electrode 13 are accommodated inside each of the first trenches 211. The other constitution of the first trenches 211 in the embodiment is the same as the other constitution of the first trenches 11 in the first embodiment described above.

A carrier extraction layer 216 has a substantially rectangular tubular shape in which it extends in the thickness direction. When viewed from the thickness direction, the carrier extraction layer 216 substantially surrounds the first insulating film 12. In the embodiment, the dimension of the carrier extraction layer 216 in the second direction D2 is substantially the same as the dimension of the first trenches 211 in the second direction D2. The dimension of the carrier extraction layer 216 in the first direction D1 is substantially the same as the dimension of the first trenches 211 in the first direction D1. The other constitution of the carrier extraction layer 216 in the embodiment is the same as the other constitution of the carrier extraction layer 16 in the first embodiment described above.

A source layer 217 has a substantially rectangular cylindrical shape in which it extends in the thickness direction. When viewed from the thickness direction, the source layer 217 surrounds the first electrode 13. When viewed from the thickness direction, the source layer 217 surrounds the carrier extraction layer 216. The source layer 217 is in contact with the carrier extraction layer 216. The dimension S2 in the second direction D2 of the source layer 217 and the dimension S1 in the first direction D1 of the source layer 217 are the same dimension. Therefore, the first distance L1 and the second distance L2 have the same dimension. The other constitution of the source layer 217 in the embodiment is the same as the other constitution of the source layer 217 in the first embodiment described above.

When viewed from the thickness direction, the second trench 220 surrounds each of the plurality of first trenches 211. The second trench 220 has the plurality of first extension portions 221 and the plurality of second extension portions 222.

Each of the first extension portions 221 is a portion of the second trench 220 which extends in a first direction D1. The first extension portions 221 extend linearly in the first direction D1. Each of the plurality of first extension portions 221 is disposed between the first trenches 211 which are disposed adjacent to each other in the second direction D2. The width W21 of each of the first extension portions 221 is greater than the width W11 of each of the first extension portions 21 in the first embodiment described above.

Each of the second extension portions 222 is a portion of the second trench 220 which extends in the second direction D2. The second extension portions 222 extend linearly in the second direction D2. Each of the plurality of second extension portions 222 is disposed between the first trenches 211 disposed adjacent to each other in the first direction D1. The width W22 of each of the second extension portions 222 is greater than the width W12 of each of the second extension portions 22 in the first embodiment described above. The width W22 of each of the second extension portions 222 is narrower than the width W21 of each of the first extension portions 221. In other words, the width W21 of each of the plurality of first extension portions 221 is greater than the width W22 of each of the plurality of second extension portions 222. The other constitution of the second trench 220 in the embodiment is the same as the other constitution of the second trench 20 in the first embodiment described above.

The second trench 220 has a second insulating film 224 and a second electrode 225 accommodated therein. The second insulating film 224 is formed on an inner surface of the second trench 220. The other constitution of the second insulating film 224 in the embodiment is the same as the other constitution of the second insulating film 24 in the first embodiment described above.

The second electrode 225 is disposed inside the entire second trench 220. When viewed in the thickness direction, the width of the portion of the second electrode 225 accommodated inside each of the first extension portions 221 is wider than the width of the portion of the second electrode 25 accommodated inside each of the first extension portions 21 of the first embodiment described above. When viewed in the thickness direction, the width of the portion of the second electrode 225 accommodated inside each of the second extension portions 222 is wider than the width of the portion of the second electrode 25 accommodated inside each of the second extension portions 22 in the first embodiment described above. That is to say, the width of the second electrode 225 is wider than the width of the second electrode 25 in the first embodiment. Thus, the electrical resistance of the second electrode 225 is less than the electrical resistance of the second electrode 25 in the first embodiment. The other constitution of the second electrode 225 in the embodiment is the same as the other constitution of the second electrode 25 in the first embodiment described above.

In the embodiment, each of the plurality of first extension portions 221 has a conductive portion 226 disposed therein. The width of the conductive portion 226 in the embodiment is greater than the width of the conductive portion 26 in the first embodiment described above. Thus, since a cross-sectional area of the conductive portion 226 is greater than a cross-sectional area of the conductive portion 26 in the first embodiment, the electrical resistance of the conductive portion 226 is less than the electrical resistance of the conductive portion 26 in the first embodiment. As described above, the electrical resistance of the second electrode 225 is less than the electrical resistance of the second electrode 25 in the first embodiment. Therefore, in the embodiment, since the gate resistance Rg can be reduced more than that of the first embodiment, the potential of the entire second electrode 225 can be more suitably made uniform. The other constitution of the conductive portion 226 in the embodiment is the same as the other constitution of the conductive portion 26 in the first embodiment described above.

In the embodiment, each of the plurality of second extension portions 222 has a second conductive portion 226b disposed therein. Although not shown in the drawings, the second conductive portion 226b extends upward from an inside of the second extension portion 222. The second conductive portion 226b is electrically connected to the second electrode 225. A portion on the upper side of the second conductive portion 226b is located inside the insulation layer 30. Thus, the second conductive portion 226b is insulated from the source electrode 32. Furthermore, the second conductive portion 226b is insulated from each of the drift layer 14, the base layer 15, the source layer 217, and the source electrode 32 using the second insulating film 224.

The second conductive portion 226b is connected to the conductive portion 226. Therefore, a part of a gate current that is a current flowing through the second electrode 225 flows through the conductive portion 226 and the second conductive portion 226b. Thus, in the embodiment, the gate resistance Rg can be more suitably reduced as compared to the case in which the second conductive portion 226b is not provided in each of the second extension portions 222. The other constitution of the second conductive portion 226b is the same as the other constitution of the conductive portion 226 described above. The other constitution of the semiconductor device 210 in the embodiment is the same as the other constitution of the semiconductor device 10 in the first embodiment described above.

Also, in the embodiment, as described above, the first distance L1 and the second distance L2 have the same dimension. For this reason, as in the first embodiment described above, the first distance L1 can be prevented from becoming too short, and thus the threshold voltage of the semiconductor device 210 can be prevented from increasing.

Furthermore, in the embodiment, as described above, the gaps Pc between the first trenches 211 are all the same length, and thus the gaps between the first electrodes 13 can be made have the same gap. Therefore, the withstand voltage between the first electrodes 13 can be made uniform and the withstand voltage of the semiconductor device 210 can be increased.

### Third Embodiment

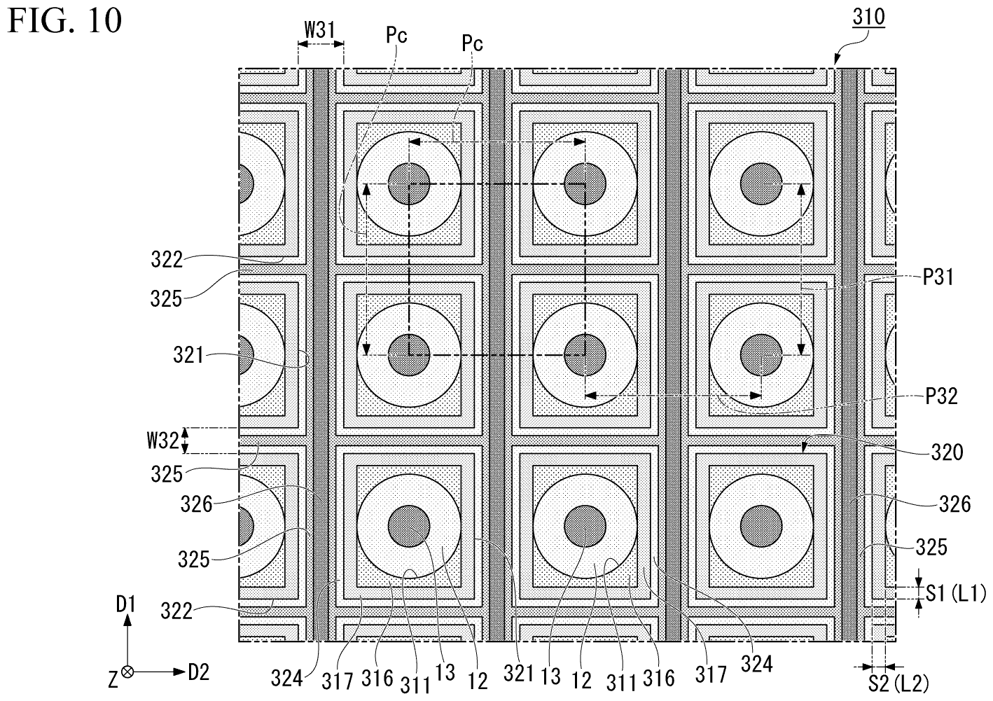

FIG. 10 is a plan view showing a semiconductor device 310 in the third embodiment. In the embodiment, when viewed from the thickness direction, a rectangle, having centers of four first trenches 311 disposed adjacent to each other as vertexes, is a square. In the following description, the same constituent elements as those in the above-described first embodiment are denoted by the same reference numerals and the description thereof will be omitted. The semiconductor device 310 in the embodiment includes a plurality of first trenches 311 and a second trench 320. The semiconductor device 310 includes a semiconductor substrate 40 (refer to FIG. 2), an insulation layer 30 (refer to FIG. 2), and a source electrode 32 (refer to FIG. 2).

As shown in FIG. 10, in the embodiment, the first trenches 311 are disposed side by side in each first direction D1 and each second direction D2. When viewed from the first direction D1, the first trenches 311 included in each of the two first trench rows disposed adjacent to each other in the first direction D1 are disposed so that they overlap each other. In the embodiment, the second direction D2 is orthogonal to the first direction D1.

In the embodiment, a gap P31 between the first trenches 311 in the first direction D1 and a gap P32 between the first trenches 311 in the second direction D2 have the same dimension. When viewed from the thickness direction, lengths Pc of the four sides of a rectangle, having the centers of the four first trenches 311 adjacent to each other as vertexes, are the same. In the embodiment, when viewed from the thickness direction, a rectangle, having the centers of the four first trenches 311 adjacent to each other as vertexes, is a square. Each of the first trenches 311 has the first insulating film 12 and the first electrode 13 accommodated therein. The other constitution of the first trench 311 in the embodiment is the same as the other constitution of the first trench 11 of the first embodiment described above.

A carrier extraction layer 316 has a substantially rectangular tubular shape extending in the thickness direction. When viewed in the thickness direction, the carrier extraction layer 316 substantially surrounds the first insulating film 12. In the embodiment, a dimension in the first direction D1 of the carrier extraction layer 316 is greater than a dimension in the second direction D2 of the carrier extraction layer 316.

The other constitution of the carrier extraction layer 316 in the embodiment is the same as the other constitution of the carrier extraction layer 16 in the first embodiment described above.

A source layer 317 has a substantially rectangular cylindrical shape extending in the thickness direction. When viewed from the thickness direction, the source layer 317 surrounds the first electrode 13. When viewed from the thickness direction, the source layer 317 surrounds the carrier extraction layer 316. The dimension S2 in the second direction D2 of the source layer 317 and the dimension S1 in the first direction D1 of the source layer 317 have the same dimension. Therefore, the first distance L1 and the second distance L2 have the same dimension. The other constitution of the source layer 317 in the embodiment is the same as to the other constitution of the source layer 17 in the first embodiment described above.

When viewed from the thickness direction, the second trench 320 surrounds each of the plurality of first trenches 311. The second trench 320 has a plurality of first extension portions 321 and a plurality of second extension portions 322.

Each of the first extension portions 321 is a portion of the second trench 320 which extends in the first direction D1. Each of the first extension portions 321 extends linearly in the first direction D1. Each of the plurality of first extension portions 321 is disposed between the first trenches 311 disposed adjacent to each other in the second direction D2.

Each of the second extension portions 322 is a portion of the second trench 320 which extends in the second direction D2. Each of the second extension portions 322 extends linearly in the second direction D2. Each of the plurality of second extension portions 322 is disposed between the first trenches 311 disposed adjacent to each other in the first direction D1. A width W32 of each of the second extension portions 322 is narrower than a width W31 of each of the first extension portions 321. In other words, the width W31 of each of the plurality of first extension portions 321 is greater than the width W32 of each of the plurality of second extension portions 322. The other constitution of the second trench 320 in the embodiment is the same as the other constitution of the second trench 20 in the first embodiment described above.

The second trench 320 has a second insulating film 324 and a second electrode 325 accommodated therein. The second insulating film 324 is formed on the inner surface of the second trench 320. The other constitution of the second insulating film 324 in the embodiment is the same as the other constitution of the second insulating film 24 in the first embodiment described above.

The second electrode 325 is disposed inside the entire second trench 320. When viewed in the thickness direction, a width of a portion of the second electrode 325 accommodated inside each of the first extension portions 321 is wider than a width of a portion of the second electrode 325 accommodated inside each of the second extension portions 322. The other constitution of the second electrode 325 in the embodiment is the same as the other constitution of the second electrode 25 in the first embodiment described above.

Each of the plurality of first extension portions 321 has a conductive portion 326 disposed therein. In each of the plurality of second extension portions 322, the conductive portion 326 is not disposed. Thus, since the width W32 of each of the second extension portions 322 can be narrower than the width W31 of each of the first extension portions 321, a dimension in the first direction D1 of the carrier extraction layer 316 can be greater than a dimension in the second direction D2 thereof. The other constitution of the conductive portion 326 in the embodiment is the same as the other constitution of the conductive portion 26 in the first embodiment described above. The other constitution of the semiconductor device 310 in the embodiment is the same as the other constitution of the semiconductor device 10 in the first embodiment described above.

According to the embodiment, the gap P31 between the first trenches 311 in the first direction D1 and the gap P32 between the first trenches 311 in the second direction D2 have the same dimension. Thus, it is easy to reduce the difference in the gap between the first electrodes 13. Therefore, the withstand voltage between the first electrodes 13 can be easily made uniform and the withstand voltage of the semiconductor device 310 can be increased.

According to the embodiment, when viewed from the thickness direction, a rectangle, having the centers of the four first trenches 311 adjacent to each other as vertexes, is a square. Thus, this makes it easier to suitably reduce the difference in the gap between the first electrodes 13. Therefore, the withstand voltage between the first electrodes 13 can be more easily and suitably made uniform and the withstand voltage of the semiconductor device 310 can be more suitably increased.

Also, in the embodiment, each of the first extension portions 321 has the conductive portion 326 disposed therein and each of the second extension portions 322 does not have the conductive portion 326 disposed therein. Thus, as described above, since the width W32 of each of the second extension portions 322 can be narrower than the width W31 of each of the first extension portions 321, the dimension in the first direction D1 of the carrier extraction layer 316 can be greater than the dimension in the second direction D2 thereof. Therefore, since the cross-sectional area of the carrier extraction layer 316 can be prevented from becoming too small, the avalanche resistance can be prevented from decreasing. Furthermore, since the gap Pc between the first trenches 311 can be made small, the on-resistance of the semiconductor device 310 can be reduced. Therefore, the on-resistance of the semiconductor device 310 can be reduced while suppressing a decrease in the avalanche resistance.

Moreover, in the embodiment, as described above, the width W32 of each of the second extension portions 322 can be narrower than the width W31 of each of the first extension portions 321. Thus, it is easy to make the gap between each of the first trenches 311 small while keeping the first distance L1 and the second distance L2 the same dimension. Therefore, since the first distance L1 can be prevented from becoming too short, the threshold voltage of the semiconductor device 310 can be prevented from increasing. This is because the P-type impurity in the carrier extraction layer 316 can be prevented from diffusing too much toward the second electrode 325, and thus an increase in the concentration of the P-type impurity in the carrier extraction layer 316 can be prevented. Furthermore, since the gap between the first trenches 311 can be easily reduced, the on-resistance of the semiconductor device 310 can be reduced. Therefore, the on-resistance of the semiconductor device 310 can be reduced while suppressing an increase in the threshold voltage.

### Fourth Embodiment

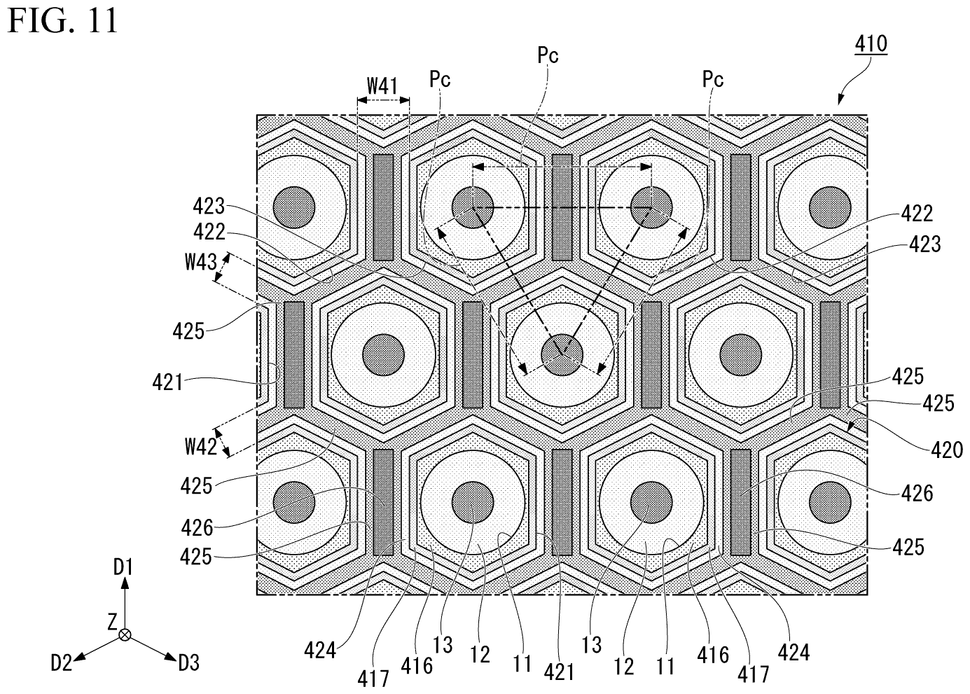

FIG. 11 is a plan view showing a semiconductor device 410 in a fourth embodiment. In the embodiment, when viewed in the thickness direction, a second trench 420 has a honeycomb shape in which it surrounds each of the plurality of first trenches 11. In the following description, constituent elements having the same aspects as those in the above-described first embodiment are denoted by the same reference numerals and description thereof will be omitted. The semiconductor device 410 in the embodiment includes a plurality of first trenches 11 and a second trench 420. The semiconductor device 410 includes the semiconductor substrate 40 (refer to FIG. 2), the insulation layer 30 (refer to FIG. 2), and the source electrode 32 (refer to FIG. 2).

As shown in FIG. 11, the first trenches 11 are staggered in a direction which is orthogonal to the thickness direction. In the embodiment, the disposition of each of the first trenches 11 is the same as the disposition of each of the first trenches 11 in the first embodiment. Therefore, when viewed from the thickness direction, the lengths Pc of the three sides of a triangle, having the centers of the three first trenches 11 disposed adjacent to each other as vertexes, are the same. For this reason, the gaps Pc between the first trenches 11 have all the same length. Each of the first trenches 11 has the first insulating film 12 and the first electrode 13 accommodated therein.

A carrier extraction layer 416 has a substantially hexagonal cylindrical shape in which it extends in the thickness direction. When viewed in the thickness direction, the carrier extraction layer 416 has a substantially regular hexagonal annular shape. When viewed in the thickness direction, the carrier extraction layer 416 surrounds the first insulating film 12. The other constitution of the carrier extraction layer 416 in the embodiment is the same as the other constitution of the carrier extraction layer 16 in the first embodiment described above.

A source layer 417 has a substantially hexagonal tubular shape in which it extends in the thickness direction. When viewed in the thickness direction, the source layer 417 has a substantially regular hexagonal annular shape. When viewed in the thickness direction, the source layer 417 surrounds the first electrode 13. When viewed in the thickness direction, the source layer 417 surrounds the carrier extraction layer 416. The source layer 417 is in contact with the carrier extraction layer 416. When viewed in the thickness direction, a width of the source layer 417 is substantially the same over one circumference in the circumferential direction. Therefore, a distance between the carrier extraction layer 416 and the second insulating film 424 is substantially the same over one circumference in the circumferential direction. The other constitution of the source layer 417 in the embodiment is the same as the other constitution of the source layer 17 in the first embodiment described above.

When viewed from the thickness direction, the second trench 420 surrounds each of the plurality of first trenches 11. The second trench 420 has a plurality of first extension portions 421, a plurality of second extension portions 422, and a plurality of third extension portions 423.

Each of the first extension portions 421 is a portion of the second trench 420 which extends in the first direction D1. Each of the first extension portions 421 extends linearly in the first direction D1. Each of the plurality of first extension portions 421 is disposed between the first trenches 11 which are disposed adjacent to each other in a direction which is orthogonal to both the thickness direction and the first direction D1.

Each of the second extension portions 422 is a portion of the second trench 420 which extends in the second direction D2. In the embodiment, the second direction D2 is a direction which intersects with the first direction D1. An angle between the second direction D2 and the first direction D1 is substantially 120°. Each of the second extension portions 422 extends linearly in the second direction D2. Each of the plurality of second extension portions 422 is disposed between the first trenches 11 which are adjacent to each other in a direction which is orthogonal to the second direction D2. A width W42 of each of the second extension portions 422 is narrower than a width W41 of each of the first extension portions 421.

Each of the third extension portions 423 is a portion of the second trench 420 which extends in a third direction D3. In the embodiment, the third direction D3 is a direction which is orthogonal to the thickness direction and intersects with both the first direction D1 and the second direction D2. An angle between the third direction D3 and the first direction D1 is substantially 120°. An angle between the third direction D3 and the second direction D2 is substantially 120°. Each of the third extension portions 423 extends linearly in the third direction D3. Each of the plurality of third extension portions 423 is disposed between the first trenches 11 which are adjacent to each other in a direction which is orthogonal to the third direction D3. A width W43 of each of the third extension portions 423 is narrower than the width W41 of each of the first extension portions 421. The width W43 of each of the third extension portions 423 is substantially the same dimension as the width W42 of each of the second extension portions 422. Both ends in the second direction D2 of each of the second extension portions 422 are connected to end portions in the first direction D1 of the first extension portions 421 which are different from each other. Both ends in the third direction D3 of each of the third extension portions 423 are connected to end portions in the first direction D1 of the first extension portions 421 which are different from each other. Thus, when viewed in the thickness direction, the second trench 420 has a honeycomb shape in which it surrounds each of the plurality of first trenches 11. The other constitution of the second trench 420 in the embodiment is the same as the other constitution of the second trench 20 in the first embodiment described above.

The second trench 420 has a second insulating film 424 and a second electrode 425 accommodated therein. The second insulating film 424 is formed on an inner surface of the second trench 420. When viewed from the thickness direction, the second insulating film 424 is a substantially regular hexagonal annular shape. The other constitution of the second insulating film 424 in the embodiment is the same as the other constitution of the second insulating film 24 in the first embodiment described above.

The second electrode 425 is disposed inside the entire second trench 420. When viewed in the thickness direction, a width of a portion of the second electrode 425 accommodated inside each of the first extension portions 421 is wider than a width of a portion of the second electrode 425 accommodated inside each of the second extension portions 422 and a width of a portion of the second electrode 425 accommodated inside each of the third extension portions 423. The other constitution of the second electrode 425 in the embodiment is the same as the other constitution of the second electrode 25 in the first embodiment described above.

Each of the plurality of first extension portions 421 has a conductive portion 426 disposed therein. The conductive portion 426 is not disposed in each of the plurality of second extension portions 422 and the plurality of third extension portions 423. Thus, as in the above-described first embodiment, the gate resistance Rg can be reduced as compared to the case in which the conductive portion 426 is not provided in each of the first extension portions 421. Therefore, the potential of the entire second electrode 425 can be uniformed in an appropriate manner. The other constitution of the conductive portion 426 in the embodiment is the same as the other constitution of the conductive portion 26 in the first embodiment described above. The other constitution of the semiconductor device 410 in the embodiment is the same as the other constitution of the semiconductor device 10 in the first embodiment described above.

Also, in the embodiment, as described above, each of the first extension portions 421 has the conductive portion 426 disposed therein. Each of the second extension portions 422 and each of the third extension portions 423 do not have the conductive portion 426 disposed therein. Thus, since the width W42 of each of the second extension portions 422 and the width W43 of each of the third extension portions 423 can be narrower than the width W41 of each of the first extension portions 321, the dimension in the first direction D1 of the carrier extraction layer 416 can be greater than the dimension in the second direction D2 of the carrier extraction layer 416.

According to the embodiment, the second trench 420 includes the third extension portion 423 extending in the third direction D3, each of the plurality of first extension portions 421 is disposed between the first trenches 11 adjacent to each other in the direction which is orthogonal to both the thickness direction and the first direction D1, each of the plurality of second extension portions 422 are disposed between the first trenches 11 adjacent to each other in the direction which is orthogonal to the second direction D2, and each of the plurality of third extension portions 423 are disposed between the first trenches 11 adjacent to each other in the direction which is orthogonal to the third direction D3. In addition, when viewed in the thickness direction, the second trench 420 has a honeycomb shape in which it surrounds each of the plurality of first trenches 11. For this reason, the gap between the second electrode 425 accommodated inside the second trench 420 and each of the first electrodes 13 accommodated inside each of the first trenches 11 can be prevented from becoming too large. Thus, since the concentration of the electric field on a portion of the second electrode 425 can be effectively prevented, the avalanche resistance of the semiconductor device 410 can be effectively increased.

Also, although the conductive portion 426 is disposed in each of the first extension portions 421 in the embodiment, the conductive portion 426 is not disposed in each of the second extension portions 422 and each of the third extension portions 423. Thus, as in the first embodiment described above, the width W42 of each of the second extension portions 422 and the width W43 of each of the third extension portions 423 can be made narrower than the width W41 of each of the first extension portions 421. Therefore, it is easy to reduce the gap between the first trenches 311 while maintaining the distance between the carrier extraction layer 416 and the second insulating film 424 in substantially the same dimension around the circumference. Accordingly, the on-resistance of the semiconductor device 410 can be reduced while suppressing an increase in the threshold voltage.

Furthermore, in the embodiment, the conductive portion 426 is disposed in each of the first extension portions 421 and the conductive portion 426 is not disposed in each of the second extension portions 422 and each of the third extension portions 423. Thus, as described above, since the width W42 of each of the second extension portions 422 and the width W43 of each of the third extension portions 423 can be made narrower than the width W41 of each of the first extension portions 321, the gap Pc between the first trenches 11 can be made smaller. Therefore, the on-resistance of the semiconductor device 410 can be reduced. Accordingly, the on-resistance of the semiconductor device 410 can be reduced while suppressing a decrease in the avalanche resistance.

According to at least one of the embodiments described above, by making the width of each of the plurality of second extension portions narrower than the width of each of the plurality of first extension portions, it is possible to provide a semiconductor device which can reduce on-resistance while suppressing an increase in threshold voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of first trenches which are recessed from a surface of a semiconductor substrate toward one side in a thickness direction of the semiconductor substrate and has a first electrode accommodated therein;
a second trench which is recessed from the surface toward the one side in the thickness direction and has a second electrode accommodated therein;
a first conductivity type base layer which is disposed between the first trench and the second trench and surrounds the first electrode;
a second conductivity type source layer which is disposed on the other side of the base layer in the thickness direction, in contact with the base layer, and surrounds the first electrode;
a second conductivity type drift layer which is disposed on the one side of the base layer in the thickness direction and in contact with the base layer; and
a source electrode which is disposed on the other side of the semiconductor substrate in the thickness direction and electrically connected to the first electrodes and the source layer;
wherein, when viewed from the thickness direction, the second trench surrounds each of the first trenches,
the second trench has a plurality of first extension portions which extend in a first direction orthogonal to the thickness direction and a plurality of second extension portions which extend in a second direction which is orthogonal to the thickness direction and intersects the first direction, and
a width of each of the second extension portions is narrower than a width of each of the first extension portions.

2. The semiconductor device according to claim 1, wherein a conductive portion which is connected to the second electrode is disposed in each of the first extension portions.

3. The semiconductor device according to claim 2, wherein a second conductive portion which is connected to the second electrode is disposed in each of the second extension portions, and
the second conductive portion is connected to the conductive portion.

4. The semiconductor device according to claim 2, wherein a resistivity of the conductive portion is smaller than a resistivity of the second electrode.

5. The semiconductor device according to claim 2, wherein the conductive portion is made of tungsten.

6. The semiconductor device according to claim 1, wherein a gap in a first direction between imaginary lines adjacent to each other in the first direction among imaginary lines extending in the second direction and passing through centers of the plurality of first trenches is smaller than a gap between the first trenches in the second direction.

7. The semiconductor device according to claim 1, wherein, when viewed from the thickness direction, lengths of three sides of a triangle having centers of the three first trenches disposed adjacent to each other as vertexes are the same.

8. The semiconductor device according to claim 1, wherein a gap between the first trenches in the first direction and a gap between the first trenches in the second direction have the same dimension.

9. The semiconductor device according to claim 1, wherein, when viewed from the thickness direction, a rectangle having centers of the four first trenches disposed adjacent to each other as vertexes is a square.

10. The semiconductor device according to claim 1, wherein each of the first extension portions is disposed between the first trenches which are adjacent to each other in the second direction, and
each of the second extension portions is disposed between the first trenches disposed adjacent to each other in the first direction and extends in the second direction orthogonal to the first direction.

11. The semiconductor device according to claim 1, wherein the second trench includes third extension portions which extend in a third direction which is orthogonal to the thickness direction and intersects both the first direction and the second direction,
each of the first extension portions is disposed between the first trenches which are adjacent to each other in a direction which is orthogonal to both the thickness direction and the first direction,
the plurality of second extension portions are disposed between the first trenches which are adjacent to each other in a direction which is orthogonal to the second direction,
the plurality of third extension portions are disposed between the first trenches which are adjacent to each other in a direction which is orthogonal to the third direction, and
when viewed from the thickness direction, the second trench has a honeycomb shape in which it surrounds each of the first trenches.
